(19) United States
(12) Patent Application Publication
(10) Pub. No.: US 2017/0303420 A1
(43) Pub. Date: Oct. 19, 2017

(54) MOUNTING FIXTURE FOR MOTOR DRIVER AND METHOD OF MOUNTING MOTOR DRIVER

(71) Applicant: FANUC CORPORATION, Yamanashi (JP)

(72) Inventors: Genzo NAITO, Yamanashi (JP); Kazuhiro YAMAMOTO, Yamanashi (JP)

(73) Assignee: FANUC CORPORATION, Yamanashi (JP)

(21) Appl. No.: 15/487,850

(22) Filed: Apr. 14, 2017

(30) Foreign Application Priority Data
Apr. 19, 2016 (JP) 2016-083602

(51) Int. Cl. H05K 7/14; H05K 7/20; H05K 5/00

(52) U.S. Cl. CPC H05K 7/14; H05K 5/0017; H05K 7/20136

(57) ABSTRACT

To provide a mounting fixture for a motor driver and a method of mounting the motor driver. A mounting fixture is used for mounting a motor driver on a power magnetics cabinet. The mounting fixture has a rod-like shape of a smaller diameter than multiple mounting holes of the motor driver. For mounting of the motor driver by fixing the mounting holes and multiple screw holes of the power magnetics cabinet with screws, the mounting fixture is inserted in advance into the mounting hole and the screw hole. The mounting fixture is fixed in any screw hole of the power magnetics cabinet. The position of the mounting hole of the motor driver is determined using the mounting fixture. The motor driver is fixed to the power magnetics cabinet with the screws.

This application is based on and claims the benefit of priority from Japanese Patent Application No. 2016-083602, filed on 19 Apr. 2016, the content of which is incorporated herein by reference.

### BACKGROUND OF THE INVENTION

### Field of the Invention

The present invention relates to a mounting fixture for a motor driver and a method of mounting the motor driver.

### Related Art

### (Conventional Mounting Method)

An example of a motor driver and a method of mounting the motor driver on a power magnetics cabinet will be described using FIGS. 8A to 12B. FIGS. 8A and 8B show an example of a motor driver 1. The motor driver 1 includes a controller 2 and a flange 3. As shown in FIG. 8A, in the motor driver 1, the controller 2 has the shape of a rectangular parallelepiped, and the flange 3 for mounting of the controller 2 is provided to one surface of the controller 2. The flange 3 is a rectangular flat plate slightly larger in a plan view than the surface of the controller 2 on which the controller 2 is mounted. As shown in FIG. 8B, mounting holes 31 of the motor driver 1 are formed at the four corners of the flange 3. The flange 3 extends upward and downward to a length greater than the length of the controller 2 in the vertical direction. The mounting holes 31 are arranged at the right and left corners of each of an upward residual length portion and a downward residual length portion of the flange 3.

FIGS. 9A and 9B show an example of a different motor driver 1A with an external cooling structure 4A. As shown in FIG. 9A, the motor driver 1A includes a controller 2A, a flange 3A, and the external cooling structure 4A arranged behind the flange 3A. The external cooling structure 4A includes a fan 4A1 and a heat sink 4A2. Mounting holes 3A1 are formed at the upper right and left corners of the flange 3A. Cutout-shape mounting holes 3A2 with downward pointed openings are formed at the lower right and left corners of the flange 3A. FIG. 9B is a side view of the motor driver 1A. An upper end surface 4A5 of the external cooling structure 4A is located below an upper end surface 3A5 of the flange 3A. A lower end surface 4A6 of the external cooling structure 4A is located above a lower end surface 3A6 of the flange 3A. An upper end surface 2A5 of the controller 2A is located below the upper end surface 3A5 of the flange 3A. A lower end surface 2A6 of the controller 2A is located above the lower end surface 3A6 of the flange 3A.

FIGS. 10A to 10C show an example of a power magnetics cabinet 5 and an example of a power magnetics cabinet 5A on which the motor drivers 1 and 1A are to be mounted respectively. The power magnetics cabinets 5 and 5A are metallic flat plates larger than the outer shapes of the flanges 3 and 3A respectively. Screw holes 51 are formed at positions corresponding to the multiple mounting holes 31 of the motor driver 1. Screw holes 5A1 and screw holes 5A2 are formed at positions corresponding to the multiple mounting holes 3A1 and the multiple cutout-shape mounting holes 3A2 of the motor driver 1A respectively.

FIG. 10A shows an example of the power magnetics cabinet 5 on which the motor driver 1, external cooling structure 4A of which doesn't project rearward, is to be mounted. The screw holes 51 are provided at positions corresponding to the mounting holes 31 of the motor driver 1. FIG. 10B shows an example of the power magnetics cabinet 5A on which the motor driver 1A with the external cooling structure 4A is to be mounted. The power magnetics cabinet 5A has a power magnetics cabinet cutout 5A3 in which the external cooling structure 4A of the motor driver 1A is to be fitted. In the power magnetics cabinet 5A, the screw holes 5A1 are formed at positions corresponding to the upper mounting holes 3A1 of the motor driver 1A, and the screw holes 5A2 are formed at position corresponding to the lower cutout-shape mounting holes 3A2 of the motor driver 1A. FIG. 10C is a front view of the power magnetics cabinet 5A. The power magnetics cabinet cutout 5A3 is comprised by a cutout upper side 5A5 through which the upper end surface 4A5 of the external cooling structure 4A is to pass, a cutout lower side 5A6 through which the lower end surface 4A6 of the external cooling structure 4A is to pass, and lateral sides 5A7 through which the lateral portions of the external cooling structure 4A are to pass.

FIG. 11 shows a conventional method of mounting the motor driver 1 on a wall surface 54 of the power magnetics cabinet 5. In many conventional cases, abutting contact is formed between a surface of the flange 3 of the motor driver 1 opposite the controller 2 and the wall surface 54 of the power magnetics cabinet 5. Then, the motor driver 1 is fixed with screws 6. Specifically, the mounting holes 31 formed at the flange 3 of the motor driver 1 and the screw holes 51 formed at the wall surface 54 of the power magnetics cabinet 5 are aligned with each other. Then, the screws 6 are tightened into the mounting holes 31 and the screw holes 51, thereby fixing the motor driver 1 to the wall surface 54 of the power magnetics cabinet 5.

If the motor driver 1 is heavy, the mounting holes 31 of the motor driver 1 cannot be aligned easily with the screw holes 51 of the power magnetics cabinet 5. In particular, if installation is to be done by one operator, one hand of the operator is busy in using a screwdriver. In this case, the installation becomes extremely difficult work.

### (Different Conventional Mounting Method)

A different conventional method of mounting the motor driver 1 on the wall surface 54 of the power magnetics cabinet 5 will be described by referring to FIGS. 12A and 12B. According to this example, the mounting holes 31 are formed at the upper right and left corners of the flange 3 and cutout-shape mounting holes 32 are formed at the lower right and left corners of the flange 3. The lower right and left cutout-shape mounting holes 32 have downward-opened cutouts. To mount the motor driver 1 on the power magnetics cabinet 5, the screws 6 are inserted halfway in advance into the lower two of the screw holes 51 of the power magnetics cabinet 5, as shown in FIG. 12B. Then, the flange 3 of the motor driver 1 is placed on the wall surface 54 of the power magnetics cabinet 5 so as to locate the cutout-shape mounting holes 32 of the flange 3 of the motor driver 1 above the inserted screws 6. The flange 3 is thereafter moved downward. Next, the cutout-shape mounting holes 32 are hung over portions with thread cuttings of the screws 6 and the screws 6 are tightened again. Fitting the cutout-shape mounting holes 32 to the screws 6 makes it possible to support the weight of the motor driver 1 with the screws 6 and to determine the position of the flange 3 and that of the power magnetics cabinet 5.

The following describes by referring to FIGS. 13A and 13B how the motor driver 1A with the external cooling structure 4A is mounted on the power magnetics cabinet 5A using the mounting method shown in FIGS. 12A and 12B. In the case of the motor driver 1A with the external cooling structure 4A, the external cooling structure 4A is pulled out of the power magnetics cabinet 5A through the power magnetics cabinet cutout 5A3. To allow a margin, the power magnetics cabinet cutout 5A3 is generally slightly larger than the size of the external cooling structure 4A.

As shown in FIG. 13A, trying to hang the lower cutout-shape mounting holes 3A2 of the flange 3A over the screws 6 inserted in advance into the power magnetics cabinet 5A places the upper end surface 4A5 of the external cooling structure 4A at a higher height than the cutout upper side 5A5 of the power magnetics cabinet 5A. Unfortunately, this causes interface between a region of the external cooling structure 4A near the upper end surface 4A5 and a region of the power magnetics cabinet 5A near the cutout upper side 5A5 (a part indicated by an arrow P in FIG. 13A). Specifically, the cutout-shape mounting holes 3A2 of the flange 3A each have a U-shape slot of a depth greater than the aforementioned margin. This unfortunately makes the top of the external cooling structure 4A abut on the power magnetics cabinet 5A at a place near the cutout upper side 5A5.

To prevent this, the lower end surface 4A6 of the external cooling structure 4A may be hung over the cutout lower side 5A6 of the power magnetics cabinet 5A as shown in FIG. 13B instead of hanging the cutout-shape mounting holes 3A2 of the flange 3A over the screws 6. However, this shifts the motor driver 1A downward from its proper position to a degree corresponding to a difference between the height of the power magnetics cabinet cutout 5A3 and that of the external cooling structure 4A (corresponding to the margin). This causes a problem in that the mounting holes 3A1 of the motor driver 1A are not aligned with the screw holes 5A1 of the power magnetics cabinet 5A and the cutout-shape mounting holes 3A2 of the motor driver 1A are not aligned with the screw holes 5A2 of the power magnetics cabinet 5A (a part indicated by an arrow C in FIG. 13B).

### (Other Conventional Techniques)

The following describes other conventional techniques of mounting a unit with a fixture, for example. The disclosure of patent document 1 is as follows. A hanging fixture is spanned between a wall on which a weight payload is intended to be installed and a footstep plate facing the wall. The weight payload is hung down with a chain engaged with a shaft of a wall surface abutting member of the fixture. As a result, the weight payload does not swing even if the footstep deflects, so that the position of the weight payload can stably be determined.

The disclosure of patent document 2 is as follows. During mounting of a telephone on a wall, a fixture (auxiliary mounting member) for mounting of the telephone is installed in advance on a wall surface. Multiple ribs formed at the fixture are used as a positioning guide and for winding of a telephone code, thereby facilitating positioning of the telephone and connection of a residual length code.

The disclosure of patent document 3 is as follows. A conventional technique has required provisional fixation of a motor unit to the lower surface of a part installation frame member and release of the motor unit from the provisional fixation after mounting of the motor unit on a car body. By contrast, a motor, a power magnetics part, etc. are held with multiple fixture pins on a support fixture. After mounting of the power magnetics part, etc. on the car body, the support fixture is extracted from the car body. In this way, the need for a step of provisionally fixing a motor, etc. and releasing the motor, etc. from the provisional fixation is eliminated.

The disclosure of patent document 4 is as follows. During mounting of multiple parts to be mounted such as substrates on a housing, making connection between the parts to be mounted requires complicated work in some cases such as turning the substrates inside out and mounting reinforcing plates on the back sides of the substrates. Further, positioning using a fixture for positioning of a reinforcing plate causes risk in terms of removal of the fixture, management of the fixture, and securing of working space. To solve these problems, a dowel and a screw hole for positioning of a part to be mounted are formed at the housing. In this way, the aforementioned complicated work or aforementioned risk is prevented. If a necessary configuration cannot be achieved by the housing alone, a platen for a part mounted on the back side of a substrate is installed on the housing.
Patent Document 1: Japanese Unexamined Patent Application, Publication No. H07-294294
Patent Document 2: Japanese Patent Publication No. 3553679
Patent Document 3: Japanese Patent Publication No. 5062228
Patent Document 4: Japanese Patent Publication No. 5007680

### SUMMARY OF THE INVENTION

As described above, a mounting hole of a heavy motor driver cannot be aligned easily with a screw hole of a power magnetics cabinet. Additionally, for mounting of a motor driver with an external cooling structure on a power magnetics cabinet, a method of inserting a screw in advance into a lower screw hole of the power magnetics cabinet has caused the problem of interference of the top of the external cooling structure with the power magnetics cabinet.

According to patent document 1 described above, the hanging fixture is spanned between the wall on which the weight payload is intended to be installed and the footstep plate facing the wall. Meanwhile, a power magnetics cabinet of a machine tool is generally designed so as to be minimized in size and there is generally no space for the fixture to be spanned to face the wall. Hence, a simple and space-saving configuration has been required.

Patent document 2 describers the fixture for mounting of the telephone. Where a motor driver is to be mounted on a power magnetics cabinet, multiple motor drivers should be installed at a time. Hence, preparing such fixtures entails too much cost. Thus, a fixture having a simple shape and capable of being used repeatedly for multiple motor drivers has been required.

Patent document 3 describes the support fixture with the multiple fixture pins for holding of a motor, a power magnetics part, etc. According to this support fixture, however, a power magnetics part should be designed to be responsive to each car body and a fixture should be designed to be responsive to each motor. Hence, a fixture commonly usable for various motor drivers has been required. The present invention described later requires only one fixture, thereby achieving reduction in time and effort involved in design of the fixture and reduction in cost for forming a new fixture.

Patent document 4 recites that providing the dowel and the screw hole for positioning of the part to be mounted and providing the platen to the housing eliminates the need for a fixture, management of the fixture, and working space. However, using such a housing involves complication of the configuration of the housing, causing a problem in terms of cost or maintenance.

As described above, various conventional fixtures have been devised. However, these fixtures has a drawback in that large mounting space is required, the configuration of a fixture is complicated and the fixture is expensive, designing and preparing a fixture is troublesome work, or mounting and removing a fixture is burdensome work, for example. Further, giving a structure for mounting of a part to a housing necessitates complication of the configuration of the housing to cause a problem in terms of cost or maintenance. The present invention is intended to facilitate work of installing a motor driver without complicating the shape of a power magnetics cabinet.

(1) A mounting fixture according to the present invention is used for mounting a motor driver on a power magnetics cabinet. The mounting fixture has a rod-like shape of a smaller diameter than multiple mounting holes of the motor driver. For mounting of the motor driver by fixing the mounting holes and multiple screw holes of the power magnetics cabinet with screws, the mounting fixture is inserted in advance into the mounting hole and the screw hole.

(2) The mounting fixture described in (1) may include a thread portion corresponding to the diameter of the screw holes of the power magnetics cabinet.

(3) The mounting fixture described in (1) or (2) may include an uneven portion formed along a periphery of the mounting fixture.

(4) The mounting fixture described in any one of (1), (2), or (3) may have a shape corresponding to a screwdriver tool such as a straight-head shape, a cross-head shape, or a hexagonal shape.

(5) In a method of mounting a motor driver according to the present invention, a mounting fixture for the motor driver is fixed in any screw hole of a power magnetics cabinet, the position of a mounting hole of the motor driver is determined using the fixed mounting fixture, and the motor driver is fixed to the power magnetics cabinet with a screw.

(6) The method of mounting the motor driver described in (5) may include a step to be executed after some of multiple mounting holes of the motor driver and some of multiple screw holes of the power magnetics cabinet are fixed with the screw. In this step, the mounting fixture is removed from the mounting hole and the screw hole of the power magnetics cabinet and then the screw is tightened into the mounting hole and the screw hole.

According to the present invention, the position of the mounting hole of the motor driver and that of the screw hole of the power magnetics cabinet are determined using the rod-like fixture and the weight of the motor driver is supported with the rod-like fixture. This shortens time of work and reduces burden on an operator.

### BRIEF DESCRIPTION OF THE DRAWINGS

FIGS. 1A to 1C explain a mounting fixture and an example of use of the mounting fixture according to a first embodiment;

FIG. 2 shows the mounting fixture according to the first embodiment;

FIG. 3 shows a mounting fixture according to a second embodiment;

FIGS. 4A to 4C each show a mounting fixture according to a third embodiment;

FIGS. 5A and 5B each show a mounting fixture according to a fourth embodiment;

FIGS. 6A to 6F show a first step of a method of mounting a motor driver with the mounting fixture according to each embodiment;

FIGS. 7A to 7C show a second step of the method of mounting the motor driver with the mounting fixture according to each embodiment;

FIGS. 8A and 8B show an example of the motor driver;

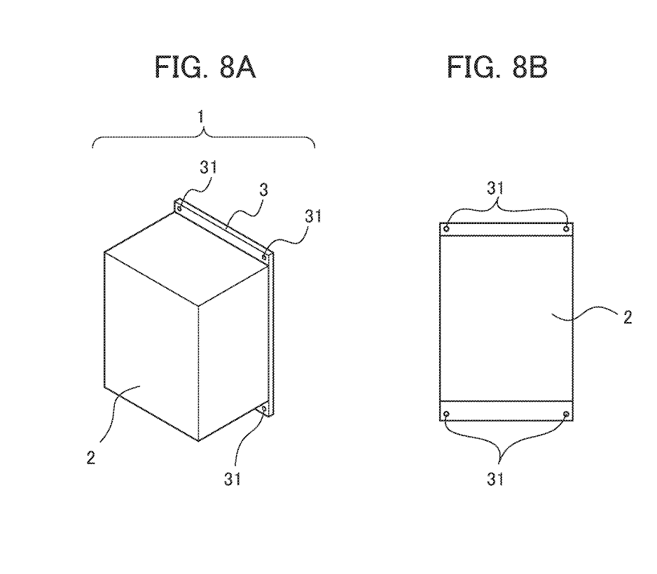

FIGS. 9A and 9B show a different example of the motor driver;

FIGS. 10A to 10C each show an example of a power magnetics cabinet on which the motor driver is to be mounted;

FIG. 11 shows a conventional method of mounting the motor driver;

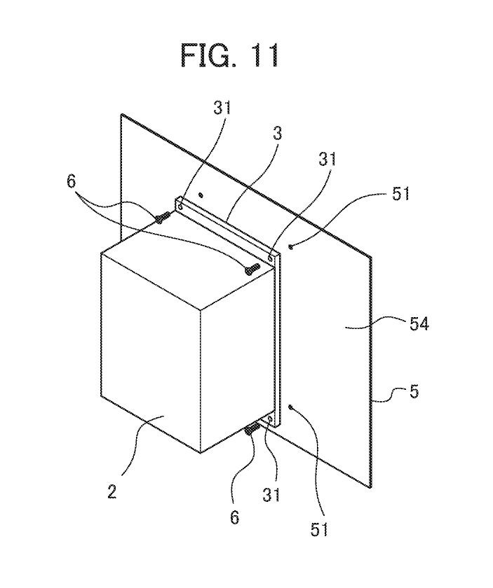

FIGS. 12A and 12B show a different conventional method of mounting the motor driver; and

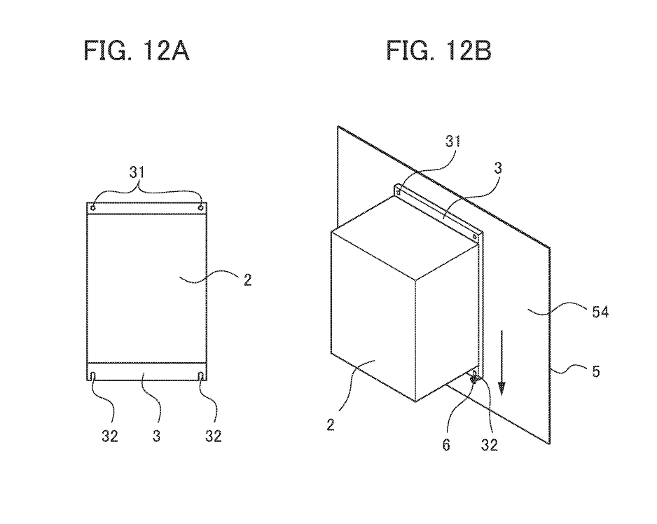

FIGS. 13A and 13B show a different conventional method of mounting the motor driver.

### DETAILED DESCRIPTION OF THE INVENTION

Embodiments of the present invention will be described below in detail by referring to the drawings. In the description of a second embodiment and a subsequent description, configurations common to those of a first embodiment will be given the same signs and explanation of such configurations will be omitted. According to the embodiments of the present invention, a mounting fixture for a motor driver has a rod-like shape of a smaller diameter than a mounting hole of the motor driver. The motor driver is mounted on a power magnetics cabinet using the mounting fixture.

According to the embodiments of the present invention, before the motor driver is mounted on the power magnetics cabinet, rod-like fixtures are inserted into some of screw holes of the power magnetics cabinet. Mounting holes of the motor driver are guided along the rod-like fixtures, thereby determining the positions of the mounting holes of the motor driver and those of the screw holes of the power magnetics cabinet. The diameter of the rod-like fixtures is smaller than that of the mounting holes of the motor driver. Thus, the mounting holes of the motor driver can let the rod-like fixtures pass through from the axis direction of the rod-like fixtures.

According to the embodiments of the present invention, the weight of the motor driver is supported with the rod-like mounting fixtures. Thus, an operator is not required to support the motor driver to reduce work burden. After positioning of the motor driver is finished, a screw hole of the power magnetics cabinet into which the rod-like mounting fixture has not been inserted is fixed with a screw. Then, the rod-like mounting fixtures are removed from the screw holes and these screw holes are fixed with screws. In this way, work of mounting the motor driver is finished. This method easily achieves mounting of the motor driver on the power magnetics cabinet even by one operator. Thus, this method is expected to shorten time of the work and reduce burden on the operator.

### First Embodiment

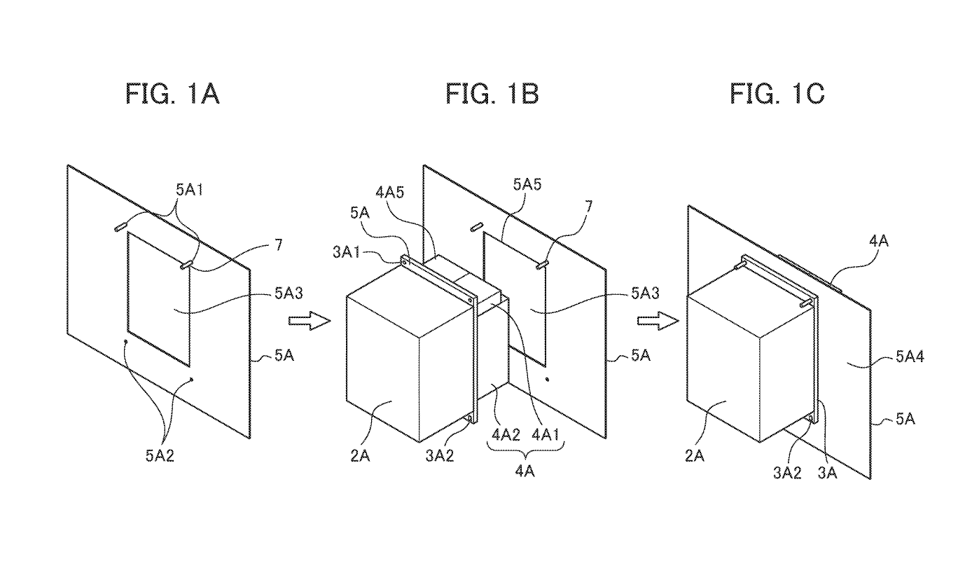

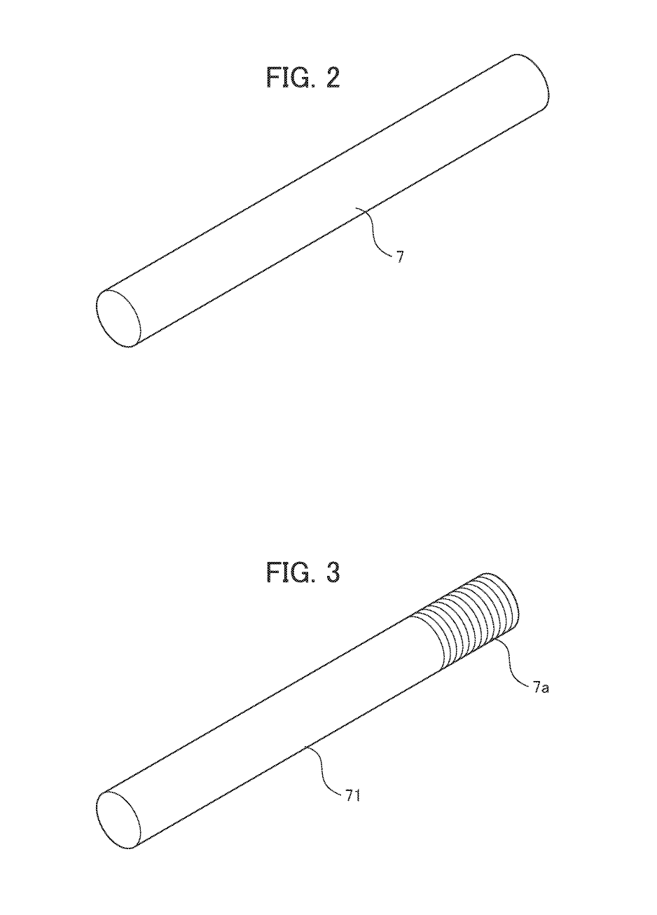

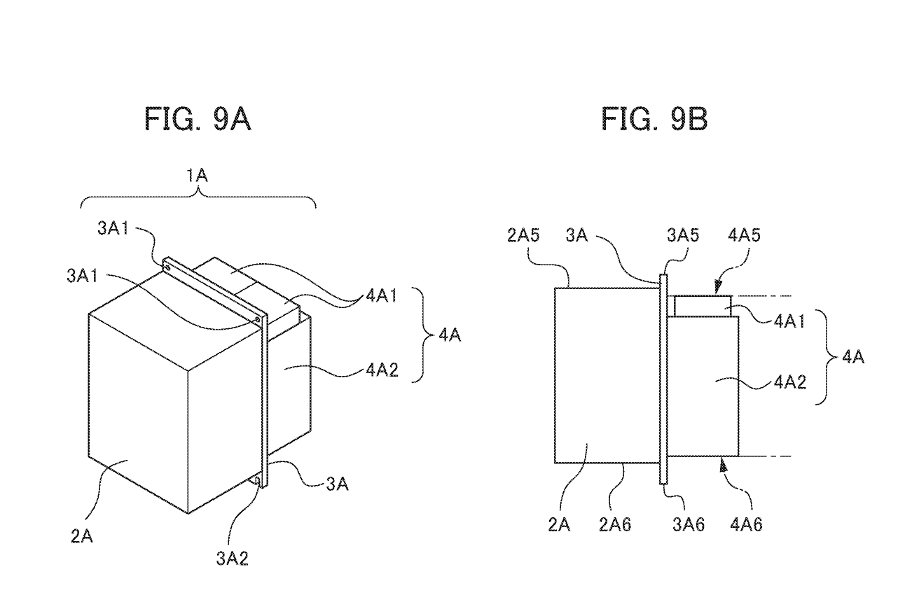

A first embodiment of the present invention will be described using FIGS. 1A to 2. The motor driver 1A with the external cooling structure 4A shown in FIGS. 9A and 9B is suitably used in the embodiments of the present invention. As shown in FIG. 1B, the motor driver 1A used in the embodiments of the present invention includes a controller 2A, a flange 3A, and the external cooling structure 4A. The external cooling structure 4A includes a fan 4A1 and a heat sink 4A2. The flange 3A has mounting holes 3A1 formed at the upper right and left corners of the flange 3A. The flange 3A has cutout-shape mounting holes 3A2 formed at the lower right and left corners of the flange 3A. The cutout-shape mounting holes 3A2 have downward-opened U-shape cutouts to form U-shape slots. The cutout-shape mounting holes 3A2 may have an ellipsoidal shape or a gourd shape. Such a shape may be employed as the shape of the mounting holes at the upper right and left corners. In the motor driver 1A, the flange 3A and the controller 2A have substantially the same width in the horizontal direction. However, this is not the only widths of the flange 3A and the controller 2A but the width of the flange 3A in the horizontal direction may be larger than the corresponding width of the controller 2A. Further, mounting holes of an appropriate number may be formed at a residual length portion of the flange 3A.

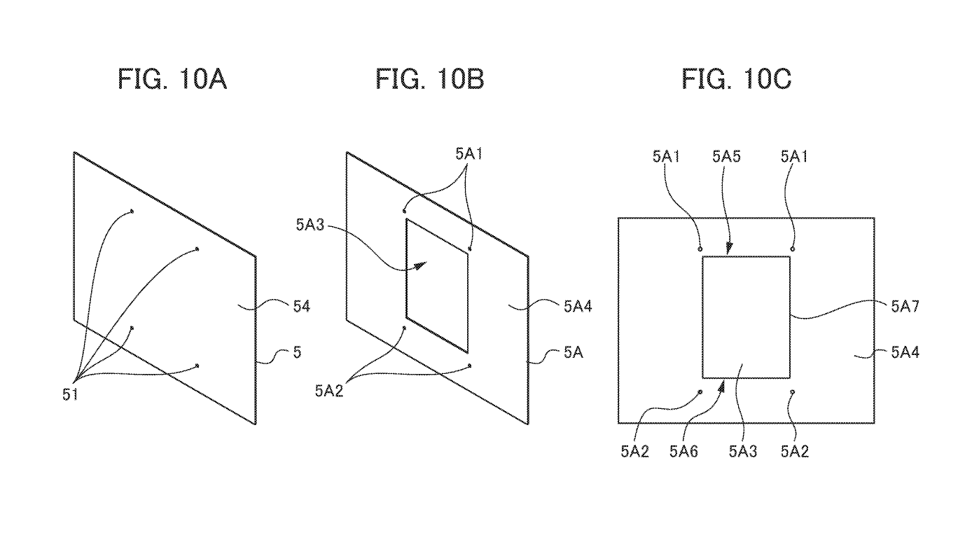

FIG. 1A shows a power magnetics cabinet 5A on which the motor driver 1A is to be mounted. This power magnetics cabinet 5A is the same as the power magnetics cabinet 5A shown in FIG. 10B. The power magnetics cabinet 5A has screw holes 5A1 and screw holes 5A2 formed at positions corresponding to the multiple mounting holes 3A1 and the multiple cutout-shape mounting holes 3A2 of the motor driver 1A respectively. As shown in FIG. 1A, a mounting fixture 7 according to the first embodiment of the present invention has a circular columnar rod-like structure that allows the mounting fixture 7 to be inserted into the screw hole 5A1 of the power magnetics cabinet 5A. FIG. 2 is an enlarged perspective view of the mounting fixture 7. The mounting fixture 7 can be inserted into the screw hole 5A1 or 5A2 of the power magnetics cabinet 5A by manual operation without the need of being screwed in. The “manual operation” mentioned herein means “operation not using a tool.” The mounting fixture 7 has a length sufficiently greater than a total of the thickness of the flange 3A and that of the power magnetics cabinet 5A. The length of the mounting fixture 7 is sufficient for suspending and holding the motor driver 1A. The diameter of the mounting fixture 7 is smaller than the inner diameter of the screw hole 5A1 and that of the screw hole 5A2 of the power magnetics cabinet 5A, and is determined in such a way that the mounting fixture 7 is maintained in a substantially horizontal posture when the mounting fixture 7 is inserted into the power magnetics cabinet 5A. The diameter of the mounting hole 3A1 of the flange 3A and the size of the cutout-shape mounting hole 3A2 at the bottom of the slot are determined to be greater than the outer diameter of a screw 6 and the diameter of the mounting fixture 7.

The mounting fixture 7 according to this embodiment is used as follows. As shown in FIG. 1A, before the motor driver 1A is mounted on the power magnetics cabinet 5A, the tips of the mounting fixtures 7 are inserted into the multiple upper screw holes 5A1 of the power magnetics cabinet 5A. In this state, the ends of the mounting fixtures 7 project frontward to a length sufficient for suspending the flange 3A of the motor driver 1A.

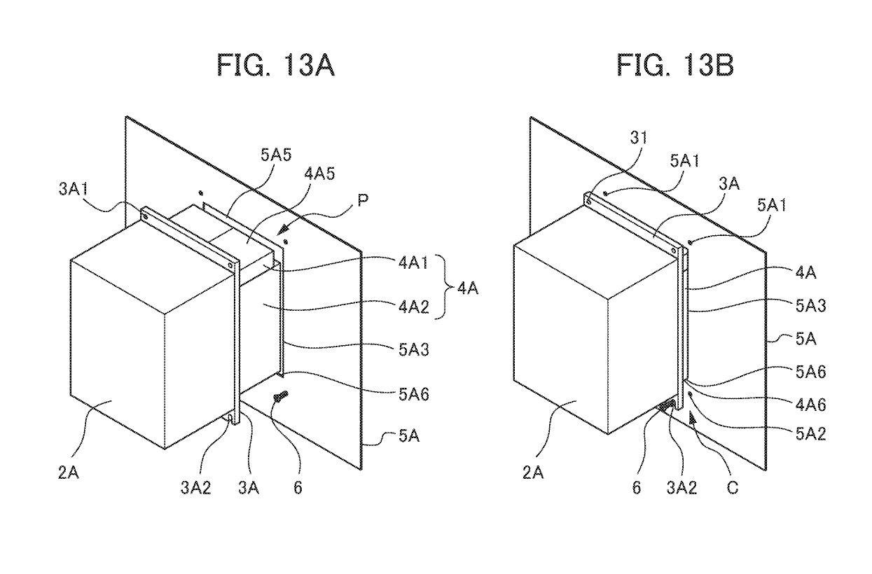

As shown in FIG. 1B, while the flange 3A and the power magnetics cabinet 5A are maintained substantially parallel to each other, the motor driver 1A is moved toward the power magnetics cabinet 5A. As shown in FIG. 1C, the external cooling structure 4A is inserted into the power magnetics cabinet cutout 5A3. Each of the multiple upper mounting holes 3A1 of the flange 3A is fitted to a corresponding one of the multiple inserted mounting fixtures 7. A surface of the flange 3A opposite the controller 2A abuts on a wall surface 5A4 of the power magnetics cabinet 5A. In this state, the mounting holes 3A1 of the flange 3A and the mounting fixtures 7 are engaged with each other to determine the position of the motor driver 1A and support the motor driver 1A at the determined position. Using the mounting fixture 7 according to this embodiment prevents the occurrence of interface between the upper end surface 4A5 of the external cooling structure 4A and the cutout upper side 5A5 of the power magnetics cabinet 5A (see FIGS. 13A and 13B) during mounting of the motor driver 1A.

### Second Embodiment

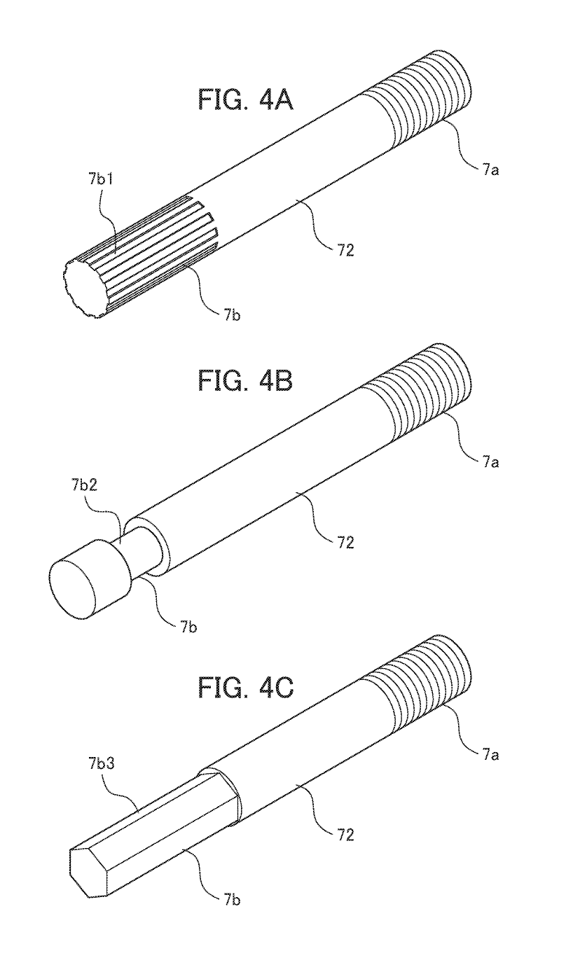

A second embodiment of the present invention will be described using FIG. 3. According to this embodiment, a mounting fixture 71 includes a thread portion 7a with a thread slot cut at one end of the mounting fixture 71. The thread portion 7a allows the mounting fixture 71 to be screwed into the screw hole 5A1 or 5A2 of the power magnetics cabinet 5A. The thread portion 7a is provided at the end of the mounting fixture 71 to be inserted into the power magnetics cabinet 5A. This achieves stable mounting of the mounting fixture 71 during installation of the mounting fixtures 71 in the screw hole 5A1 or 5A2 of the power magnetics cabinet 5A. Further, excessive insertion of screws 6 is prevented. Thus, the screws 6 are allowed to be inserted by a properly determined uniform length and allowed to project to a properly determined uniform length.

### Third Embodiment

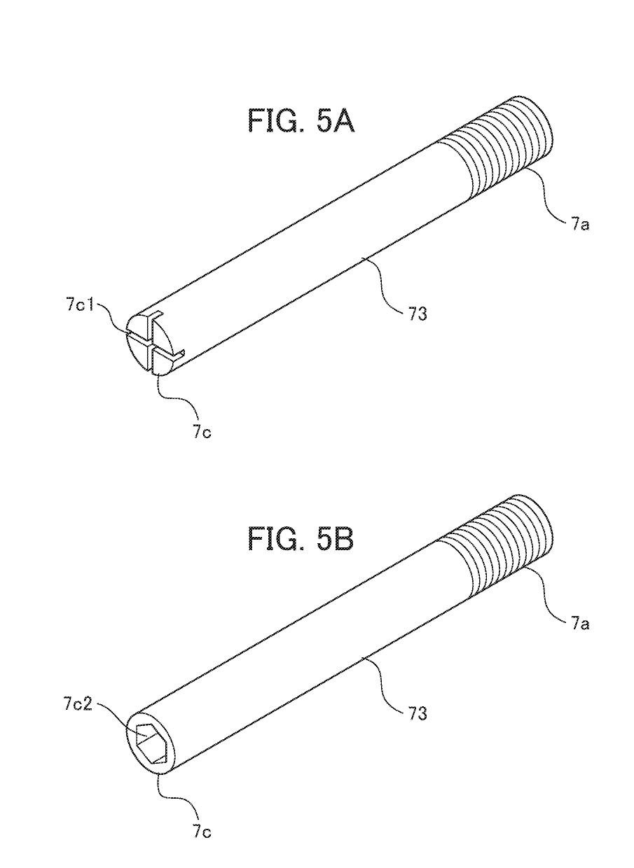

A third embodiment of the present invention will be described using FIGS. 4A to 4C. According to this embodiment, a mounting fixture 72 has an uneven portion 7b formed at an end of the mounting fixture 72 opposite the thread portion 7a. The presence of the uneven portion 7b increases friction during installation of the mounting fixture 72 in the screw hole 5A1 or 5A2 of the power magnetics cabinet 5A. This facilitates installation of a fixture by manual operation.

FIGS. 4A to 4C show a first example, a second example, and a third example respectively of the uneven portion. FIG. 4A shows the first example of the uneven portion. Multiple axially extending slots 7b1 are formed along the periphery of the end of the mounting fixture 72. The sectional shape of the slots 7b1 can be a semi-circular shape, a rectangular shape, or an inverted trapezoidal shape, for example. By gripping the mounting fixture 72 and rotating the slots 7b1 with fingers, rotational power can be transmitted to the mounting fixture 72 without causing slipping of the fingers.

FIG. 4B shows the second example of the uneven portion. The mounting fixture 72 has a slot 7b2 cut in a surface of the end of the mounting fixture 72 along the axis of the mounting fixture 72. The sectional shape of the slot 7b2 can be a semi-circular shape, a rectangular shape, or a trapezoidal shape, for example. The second example of the uneven portion further increases frictional force acting in the axial direction, so that drop of the motor driver 1A can be prevented.

FIG. 4C shows the third example of the uneven portion. Multiple cutting planes 7b3 are formed at the surface of the end of the mounting fixture 72 to form a polygonal uneven shape in an axially-taken sectional view. FIG. 4C shows an example where the uneven shape is a hexagonal shape. The shape of the uneven portion 7b is not limited to the above-described shapes, as long as a maximum diameter of the mounting fixture 72 does not exceed the diameter of the mounting holes 3A1 and 3A2 of the motor driver 1A. The mounting fixture 72 according to this embodiment includes the thread portion 7a. The mounting fixture 7 without the thread portion 7a according to the first embodiment may also include the uneven portion 7b.

### Fourth Embodiment

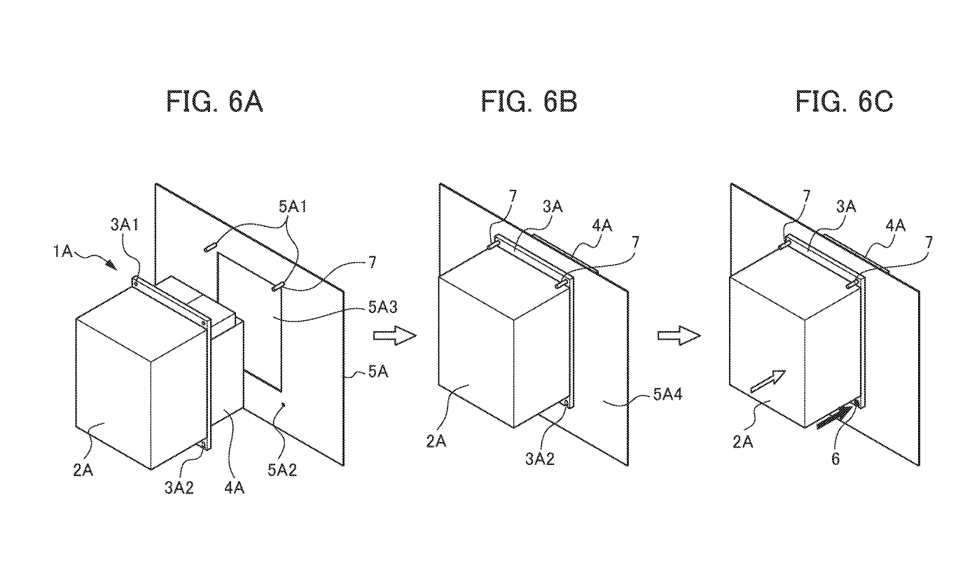

A fourth embodiment of the present invention will be described using FIGS. 5A and 5B. According to this embodiment, a bit shape portion 7c of a shape responsive to a screwdriver, etc. is formed at an end surface of a mounting fixture 73 opposite the thread portion 7a. By using the bit shape portion 7c of a shape responsive to a screwdriver, etc., the mounting fixture 73 can be installed in the screw hole 5A1 or 5A2 of the power magnetics cabinet 5A with a tool such as a screwdriver.

FIGS. 5A and 5B show a first example and a second example respectively of the bit shape portion. FIG. 5A shows the first example of the bit shape portion. To allow use of a cross-head screwdriver, a cross-shape slot 7c1 is formed at the end surface of the mounting fixture 73. As shown in FIG. 5A, slots crossing each other are cut at the end surface of the mounting fixture 73. FIG. 5B shows the second example of the bit shape portion. To allow use of a hexagonal wrench, a hexagonal hole 7c2 is formed at the end surface of the mounting fixture 73. Various shapes such as a shape responsive to a straight-head screwdriver are applicable in addition to the above-described cross-head shape and the hexagonal shape.

The first to third examples of the uneven portion formed along the periphery of the end of the mounting fixture 72 according to the above-described third embodiment may also be provided in the fourth embodiment. This configuration allows attachment of the mounting fixture 73 to the power magnetics cabinet 5A either by manual operation or with a tool. To prevent drop of the mounting fixture 73 from a tool, a screwdriver with a magnet may be used. In consideration of such use, the mounting fixture 73 is further preferably made of a ferromagnetic material such as iron. The mounting fixture 73 according to this embodiment includes the thread portion 7a. The mounting fixture 7 without the thread portion 7a according to the first embodiment may also include the bit shape portion 7c, or the bit shape portion 7c and the uneven portion 7b.

### (Embodiment of Method of Mounting Motor Driver)

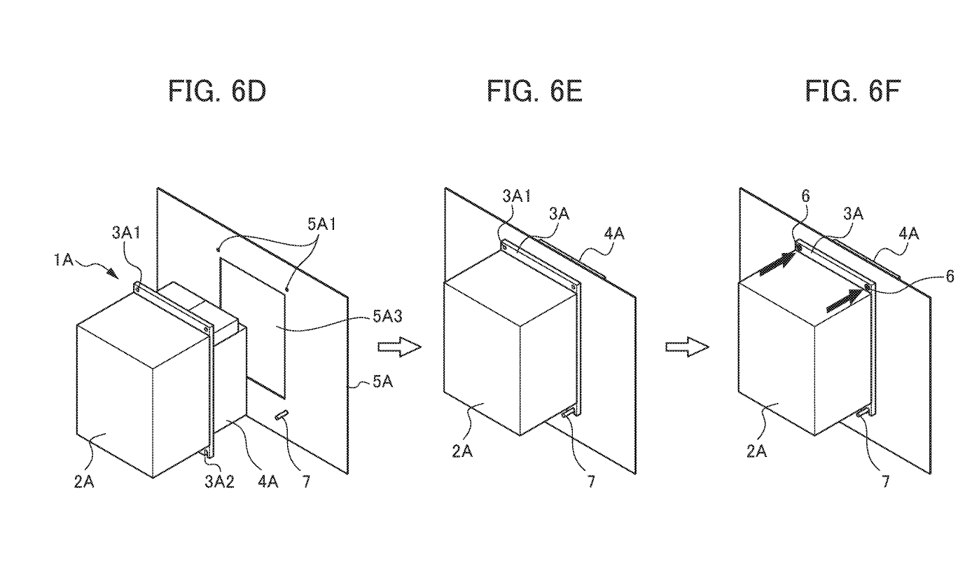

A first step of a method of mounting the motor driver 1A on the power magnetics cabinet 5A by using the mounting fixture 7 according to each embodiment will be described by referring to FIGS. 6A to 6F. FIGS. 6A to 6C explain a first mounting method by which the mounting fixture 7 is applied to the upper screw hole 5A1 of the power magnetics cabinet 5A.

As shown in FIG. 6A, before the motor driver 1A is mounted on the power magnetics cabinet 5A, the respective tips of the mounting fixtures 7 are inserted into the two upper screw holes 5A1 of the power magnetics cabinet 5A. Next, while the flange 3A and the power magnetics cabinet 5A are maintained substantially parallel to each other, the motor driver 1A is moved toward the power magnetics cabinet 5A. As shown in FIG. 6B, the external cooling structure 4A is inserted into the power magnetics cabinet cutout 5A3. The motor driver 1A is moved further to make fits between the two upper mounting holes 3A1 of the flange 3A and the two mounting fixtures 7. The motor driver 1A is moved until the back surface of the flange 3A abuts on the front-side wall surface 5A4 of the power magnetics cabinet 5A. This forms engagements between the mounting holes 3A1 of the flange 3A and the mounting fixtures 7 to determine the position of the motor driver 1A and support the motor driver 1A at the determined position. As shown by an arrow in FIG. 6C, the screws 6 are tightened into the two lower cutout-shape mounting holes 3A2 of the flange 3A to connect the two lower cutout-shape mounting holes 3A2 tightly to the screw holes 5A2 of the power magnetics cabinet 5A.

FIGS. 6D to 6F explain a second mounting method by which the mounting fixture 7 is applied to the lower screw hole 5A2 of the power magnetics cabinet 5A. As shown in FIG. 6D, before the motor driver 1A is mounted on the power magnetics cabinet 5A, the respective tips of the mounting fixtures 7 are inserted into the two lower screw holes 5A2 of the power magnetics cabinet 5A. As shown in FIG. 6E, the motor driver 1A is moved to form engagements between the lower cutout-shape mounting holes 3A2 of the flange 3A and the mounting fixtures 7, thereby determining the position of the motor driver 1A relative to the power magnetics cabinet 5A and supporting the motor driver 1A at the determined position. As shown by arrows in FIG. 6F, the screws 6 are tightened into the two upper mounting holes 3A1 of the flange 3A to connect the two upper mounting holes 3A1 tightly to the screw holes 5A1 of the power magnetics cabinet 5A.

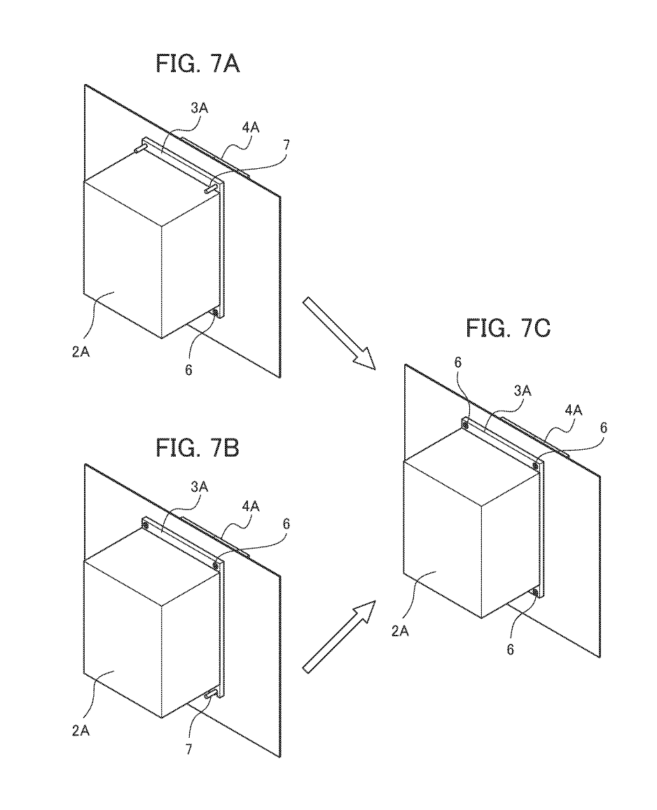

FIGS. 7A to 7C show a second step of the method of mounting the motor driver 1A on the power magnetics cabinet 5A. The second step described herein starts from a state formed by the above-described first step of the mounting method where screws are tightened into some of the mounting holes 3A1 and the cutout-shape mounting holes 3A2 of the flange 3A, while some of the mounting holes 3A1 and the cutout-shape mounting holes 3A2 are supported with the mounting fixtures 7. The second step is a step of tightening screws into all the mounting holes 3A1 and all the cutout-shape mounting holes 3A2.

FIG. 7A shows a state formed by the step of FIG. 6C of the first mounting method where screws are tightened into the lower cutout-shape mounting holes 3A2. In this state, the mounting fixtures 7 are extracted from the upper mounting holes 3A1 of the flange 3A and the upper screw holes 5A1 of the power magnetics cabinet 5A. Then, the screws 6 are screwed into the upper mounting holes 3A1 and the upper screw holes 5A1.

FIG. 7B shows a state formed by the step of FIG. 6F of the second mounting method where screws are tightened into the upper mounting holes 3A1. In this state, the mounting fixtures 7 are extracted from the lower cutout-shape mounting holes 3A2 and the lower screw holes 5A2 of the power magnetics cabinet 5A. Then, the screws 6 are screwed into the lower cutout-shape mounting holes 3A2 and the lower screw holes 5A2. As shown in FIG. 7C, all the mounting fixtures 7 are removed and the screws 6 are tightened into all the mounting holes 3A1 and all the cutout-shape mounting holes 3A2. The above-described first and second mounting methods are examples of a mounting method in which the position of the upper screw hole 5A1 or that of the lower screw hole 5A2 of the power magnetics cabinet 5A is a position where the mounting fixture 7 is to be applied. However, a mounting position is not limited to these positions. A mounting position may be determined in a manner that depends on environment of a mounting place, for example. The mounting fixture 7 may be applied to a left screw hole 5A1 or 5A2, a right screw hole 5A1 or 5A2, or a screw hole 5A1 or 5A2 at a diagonal position. Regarding extraction of the mounting fixture 7 and tightening of a screw, the mounting fixtures 7 may be extracted from multiple mounting holes 3A1 and then screws may be tightened into these mounting holes 3A1, for example. Alternatively, extraction of the mounting fixture 7 and tightening of a screw may be done for each mounting hole 3A1, for example.

Each embodiment of the present invention achieves the following effects. With the use of the rod-like mounting fixture according to the present invention, the position of the mounting hole of the motor driver and that of the screw hole of the power magnetics cabinet can be determined and the weight of the motor driver can be supported with the rod-like mounting fixture only by inserting the mounting fixture into the power magnetics cabinet. This shortens time of work and reduces burden on an operator. The thread is formed at an end of the mounting fixture to be inserted into the power magnetics cabinet. This achieves stable mounting of the mounting fixture during installation of the mounting fixtures in the screw hole of the power magnetics cabinet. The uneven portion is formed at an end of the mounting fixture opposite the thread. This increases friction during installation of the mounting fixture in the screw hole of the power magnetics cabinet. This facilitates installation of the mounting fixture by manual operation. The bit shape portion of a shape responsive to a screwdriver, etc. is formed at an end surface of the mounting fixture opposite the thread. Thus, the mounting fixture can be installed in the screw hole of the power magnetics cabinet with a tool such as a screwdriver.

The present invention is not limited to each of the above-described embodiments or the above-described examples but modifications, improvements, etc. can be covered by the present invention as long as such modifications, improvements, etc. are in a range that achieves the purpose of the present invention. According to the present embodiments, the motor driver has four mounting holes. However, this is not the only number of the mounting holes but the number of the mounting holes may be larger than or smaller than four. According to the present embodiments, fixtures are applied to the upper two of the four screw holes of the power magnetics cabinet in one case and to the lower two of these four screw holes in the other case. However, the number of fixtures to be used is not limited to these numbers. Arrangement of fixtures to be mounted is also not limited. The mounting fixture and the mounting method using the mounting fixture described in the present embodiments are applied to the motor driver with the external cooling structure. However, this is not the only application of the mounting fixture and the mounting method but the mounting fixture and the mounting method are applicable to a motor driver without an external cooling structure. The mounting fixture may be longer or shorter than the length described in the embodiments. The length of the mounting fixture can be determined appropriately in a manner that depends on the configuration of the power magnetics cabinet, for example. The thread portion of the mounting fixture may be configured in such a manner that, during screwing of the thread portion into the power magnetics cabinet, the screwing stops when a certain length of the thread portion is in the power magnetics cabinet. Various shapes for smoothly rotating the mounting fixture are applicable. For example, the mounting fixture may have a through hole penetrating the mounting fixture in a direction crossing the axis direction of the mounting fixture. Alternatively, the mounting fixture may have a diagonally extending slot or a spiral slot formed at a surface of the mounting fixture. A surface of the uneven portion is preferably not sharpened. A slot along the periphery of the axis of the mounting fixture is not always required to extend along the entire periphery but can be formed in a partial area of the mounting fixture in the peripheral direction. Multiple slots along the periphery of the axis may be arranged in the axis direction. The uneven portion of the mounting fixture is also applied to the case where the thread portion is not provided at one end of the mounting fixture. In this case, by inserting the mounting fixture axially or rotating using the uneven portion, force required for insertion of the mounting fixture can still be reduced to allow smooth insertion of the mounting fixture into the screw hole of the power magnetics cabinet. The bit shape of the mounting fixture is also applied to the case where the thread portion is not provided at one end of the mounting fixture. Even in this case, by inserting the mounting fixture with a tool using the bit shape, the mounting fixture can still be inserted smoothly into the screw hole of the power magnetics cabinet.

### EXPLANATION OF REFERENCE NUMERALS

1, 1A Motor driver
2, 2A Controller
3, 3A Flange
31, 3A1 Mounting hole
32, 3A2 Cutout-shape mounting hole
4A External cooling structure
5, 5A Power magnetics cabinet
51, 5A1, 5A2 Screw hole
5A3 Power magnetics cabinet cutout
6 Screw
7, 71, 72, 73 Mounting fixture
7a Thread portion
7b Uneven portion
7c Bit shape portion

What is claimed is:

1. A mounting fixture used for mounting a motor driver on a power magnetics cabinet,
the mounting fixture having a rod-like shape of a smaller diameter than multiple mounting holes of the motor driver, for mounting of the motor driver by fixing the mounting holes and multiple screw holes of the power magnetics cabinet with screws, the mounting fixture being inserted in advance into the mounting hole and the screw hole.

2. The mounting fixture according to claim 1, including a thread portion corresponding to the diameter of the screw holes of the power magnetics cabinet.

3. The mounting fixture according to claim 1, including an uneven portion formed along a periphery of the mounting fixture.

4. The mounting fixture according to claim 1, having a shape corresponding to a screwdriver tool such as a straight-head shape, a cross-head shape, or a hexagonal shape.

5. A method of mounting a motor driver, wherein the mounting fixture for the motor driver as recited in claim 1 is fixed in any screw hole of a power magnetics cabinet,
a mounting hole of the motor driver lets the fixed mounting fixture pass through to determine the position of the mounting hole, and
the motor driver is fixed to the power magnetics cabinet with a screw.

6. The method of mounting the motor driver according to claim 5, wherein after some of multiple mounting holes of the motor driver and some of multiple screw holes of the power magnetics cabinet are fixed with the screw,
the mounting fixture is removed from the mounting hole and the screw hole of the power magnetics cabinet and then the screw is tightened into the mounting hole and the screw hole.
